(19) United States
(12) Patent Application Publication
(10) Pub. No.: US 2020/0251588 A1
(43) Pub. Date: Aug. 6, 2020

(54) SUPER-JUNCTION MOSFET WITH INTEGRATED SNUBBER CIRCUIT

(71) Applicant: SEMICONDUCTOR COMPONENTS INDUSTRIES, LLC, Phoenix, AZ (US)

(72) Inventors: Gary H. LOECHELT, Tempe, AZ (US); Jaume ROIG-GUITART, Oudenaarde (BE)

(73) Assignee: SEMICONDUCTOR COMPONENTS INDUSTRIES, LLC, Phoenix, AZ (US)

(21) Appl. No.: 16/451,288

(22) Filed: Jun. 25, 2019

Related U.S. Application Data
(60) Provisional application No. 62/799,158, filed on Jan. 31, 2019.

(51) Int. Cl. H01L 29/78; H01L 29/66

(52) U.S. Cl. CPC H01L 29/7813; H01L 29/66734; H01L 29/7815

(57) ABSTRACT

Systems and methods of the disclosed embodiments include a semiconductor device that includes an N-doped pillar with a gate structure configured to control a signal between a drain and a source in response to a gate voltage signal. The semiconductor device may also include a P-doped pillar with a capacitive structure. The capacitive structure capacitively couples the P-doped pillar to the gate structure to reduce ringing in the gate voltage signal.

### CROSS-REFERENCE TO RELATED APPLICATIONS

This application claims the benefit of U.S. Provisional Patent Application No. 62/799,158, filed on Jan. 31, 2019, the entire contents of which is incorporated herein by reference.

### BACKGROUND

Under certain conditions, power MOSFETs based on super-junction principles (“super-junction MOSFET”) and other semiconductor devices can suffer from ringing in electrical signals as they are switched on and off. During the switch on, the ringing is a result of the physical limits of a device starting from zero current and ramping up to the operating current. In an ideal (theoretical) switch, when the device is switched on/initiated by an input signal, the output current immediately goes from zero to the operating current. Physical devices, however, may have a ringing condition present in the output current, which oscillates quickly between high current and low current for a fraction of a second before reaching the operating current value. At the same time, the current ringing can induce voltage ringing, usually because of parasitic inductance in the affected system. Similar problems can be encountered when the device switches off.

This ringing can cause problems and/or affect the devices by causing a voltage over-stress or even an avalanche breakdown condition. Malfunction of the control circuitry can also occur through feedback from the input of the device back into the controller. This problem has been addressed previously by slowing the switching of the current signal using a snubber network, which usually comprises a capacitor and possibly a resistor. Snubber networks, however, use up an amount of the limited area of the semiconductor die and may require additional steps in the manufacturing process that vary between different device architectures and process technologies. Likewise, external snubbers increase cost, require additional circuit board space, and are limited in their effectiveness because of parasitic inductance. There is a need, therefore, for integrated snubber that does not require additional die area or process cost.

### BRIEF DESCRIPTION OF THE DRAWINGS

FIG. 1 is a plan view layout of an embodiment of a super-junction MOSFET with integrated snubber;

FIG. 2 is a cross-sectional side view of a vertical trench embodiment of a super junction MOSFET with integrated snubber along line A-A of FIG. 1;

FIG. 3 is a cross-sectional side view of a vertical trench embodiment of a super junction MOSFET with integrated snubber along line B-B of FIG. 1;

FIG. 4 is a cross-sectional side view of a vertical trench embodiment of a super junction MOSFET with integrated snubber along line C-C of FIG. 1;

FIG. 5 is a cross-sectional side view of a planar gate embodiment of a super junction MOSFET with integrated snubber along line A-A of FIG. 1;

FIG. 6A is a schematic view of cross-sectional side views showing resistive and capacitive connections within the super-junction MOSFET;

FIG. 6B is a circuit diagram of the super-junction MOSFET of FIG. 6A;

FIG. 7A is a schematic view of cross-sectional side views showing resistive and capacitive connections within the super junction MOSFET;

FIG. 7B is a circuit diagram of the super-junction MOSFET of FIG. 7A;

FIG. 8 is a plan view layout of an embodiment of a super-junction MOSFET with integrated snubber; and

FIG. 9 is a plan view layout of an embodiment of a super-junction MOSFET with integrated snubber.

### DETAILED DESCRIPTION OF THE DRAWINGS

In trench gate MOSFET devices used in power device applications, the source, gate, and drift regions are arrayed in a vertical direction (e.g., y direction) or in a lateral direction (e.g., x direction) of a semiconductor substrate. Source and drain terminals may be disposed in dielectric material in a trench that is etched in the vertical direction (e.g., a y direction) perpendicular to a major surface of the semiconductor substrate. This vertical configuration may be suitable for a power MOSFET device, as more surface space can be used as a source, and also the source and drain separation can be reduced. Reduction of the source and drain separation can increase the drain-to-source current ratings and also can allow use of an epitaxial layer for the drift region to increase the voltage blocking capability of the device.

For high-voltage planar MOSFETs, the voltage blocking capability in the drift region is developed through the combination of a thick epitaxial layer and light doping. This results in a large portion of the device resistance being in the drain and limits the performance (e.g., RDS(on)) of the device. Often, there is a trade-off between breakdown voltage and on-resistance, because increasing the breakdown voltage by incorporating a thicker and more lightly doped drift region in the device leads to a higher on-resistance. With super junction power MOSFETs utilizing the super-junction principle, N-doped and P-doped columns alternate within the epitaxial layer to reduce RDS(on) at a given voltage capability. In the ultimate power MOSFET generations, RDS(on) is minimized by shrinking N-doped and P-doped columns. This minimization can have an adverse effect of an increased non-linearity in the output capacitance. As a result of this non-linearity, large dv/dt and di/dt during switching events generate undesired current and voltage ringing.

High-voltage MOSFETs can also have a trade-off with the ringing of the gate-source voltage due to the epitaxial layer and the light doping. The ringing is improved by introducing circuit characteristics (e.g., resistance, capacitance, impedance) to the MOSFETs as described below. The characteristics are provided by circuit components added to the design of the device. These characteristics may be “tuned” to the particular circuit design by changing the physical dimensions of the circuit components. For example, increasing a length of a component may increase the resistance provided by that component.

The cross-sectional diagrams illustrated in the figures and described below are representative drawings. Processing variations, variations in aspect ratios, differences in design dimensions, and/or so forth can result in different shapes and/or non-idealities.

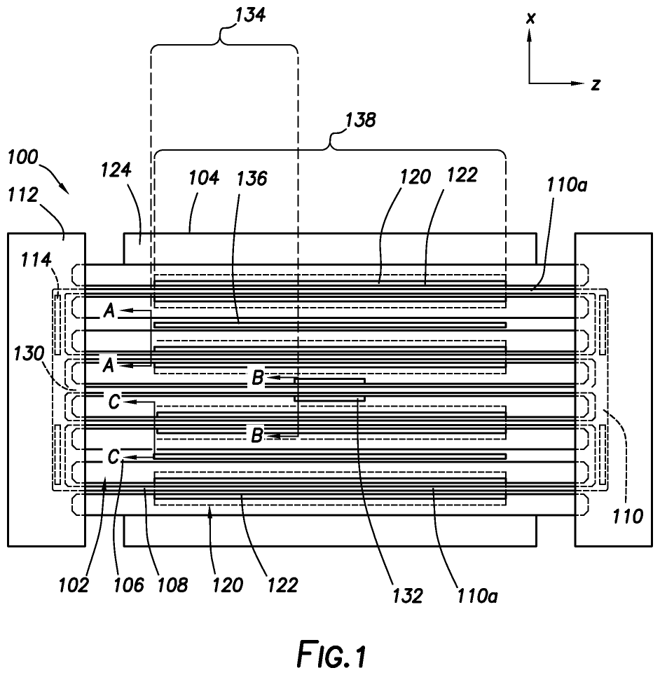

Turning now to the figures, FIG. 1 is a plan view layout of an embodiment of a super-junction MOSFET device 100 with integrated snubber. The device 100 includes a drain structure in which multiple trenches 102 with adjoining P-doped and N-doped pillars are arranged on a substrate 104. As a result, a low on-resistance RDS(on) and reduced gate charge can be realized while maintaining a high voltage. The doped pillars may be fabricated incrementally, for example, by sequentially depositing, patterning, and doping (implanting) a number of layers of semiconductor material on the semiconductor substrate 104. The semiconductor substrate can be subsequently etched to form trenches 102, which separate the P-doped pillars from the N-doped pillars with an intervening insulating material. The current path of the P-doped and N-doped columns may be dimensioned so that when the transistor is turning off and developing blocking voltage, a depletion region forms with migration of the charge carriers from the P-doped and N-doped columns resulting in high blocking-voltage capability.

As shown in FIG. 1, the super junction structure in the device 100 may include p-doped pillars 106 and n-doped pillars 108 with intervening deep trenches 102 in the semiconductor substrate 104. P-doped pillars 106 and n-doped pillars 108 (like trenches 102) extend in the z-direction. The device 100 includes a gate structure 110 that is charged when a common gate bus 112 conveys a gate voltage through gate contacts 114. The gate contacts 114 may be tuned to include various lengths and locations to ensure a strong connection between the gate structure 110 and the common gate bus 112. Arms 110a of the gate structure 110 extend along n-doped pillars 108 in the z direction to create an inversion layer or channel in the body region as described below.

In the device 100, source regions 120 are connected to source contacts 122 on each side of the n-doped pillars 108 along the z-direction. The gate structure arms 110a are placed within the device 100 in the source regions on n-doped pillars 108 also along the z-direction. The source contacts 122 are electrically connected to a common source plate 124. Thus, when the gate structure 110 is turned on, a conduction path from the drift region is created that passes through the source region 120 to the source contacts 122 and the source plate 124. The ringing that may be present in the gate-source voltage is improved by the design and shape of the gate structure 110.

The device 100 can be improved by having a capacitive relationship present within the circuitry of the device 100. For example, the device 100 may include a capacitive structure. In the embodiment illustrated in FIG. 1, the device 100 includes a gate capacitive structure 130. Other embodiments may include other capacitive structures such as a Metal-Insulator-Metal (MIM) planar structure or a Metal-Insulator-Semiconductor (MIS) planar structure. The gate capacitive structure 130 is connected to the gate structure 110, and thus may be charged with the gate structure 110, the gate contacts 114, and the gate bus 112. Although the gate capacitive structure 130 is not located within a source region 120, the gate capacitive structure 130 adds capacitance to the device 100 through the interaction between the gate capacitive structure 130 and the p-doped pillar 106. This capacitance acts as an integrated snubber that can damp the ringing which may be present in the gate-source voltage.

The snubber and the dampening effect can be further enhanced by a resistive structure which comprises a P-doped pillar contact 132 adjacent to a gate capacitive structure 130. This P-doped pillar contact 132 is connected to the source plate 124. The P-doped pillar contact 132 further comprises a P-doped pillar resistor length 134 that may be tuned depending upon the needs of the circuit of the device 100. For example, in an embodiment of the device 100 that needs a greater amount of damping, the length 134 may be increased, and conversely may be decreased in embodiments with a need for less damping. The length 134 may be tuned by changing a pattern of a single mask without otherwise changing the architecture of the device 100, and thus provides a benefit in planning and changing the fabrication of the device 100.

As further illustrated in FIG. 1, embodiments of the device 100 may include a P-doped pillar contacts 136 that are not adjacent to a gate capacitive structures 130. The P-doped pillar contacts 136 connect the source plate 124 to one of the p-doped pillars 106 where additional gate capacitance is not desired. By varying the number of p-doped pillars with either gate capacitive structures 130 or P-doped pillar contacts 136, the amount of snubbing capacitance can be selected and tuned to reduce the damping of the current and voltage ringing, improve the power efficiency of a circuit, or optimize some other system characteristic or parameter.

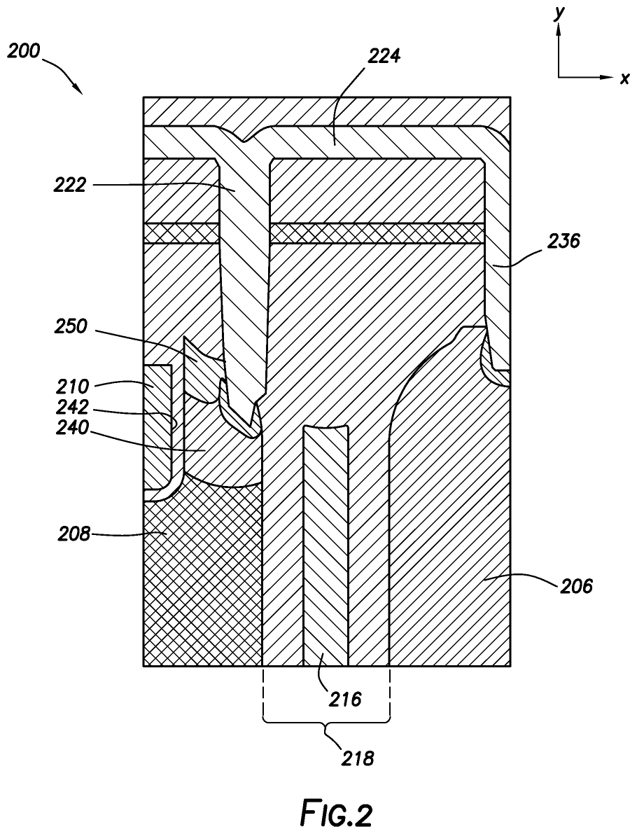

FIG. 2 is a cross-sectional side view of an embodiment of a vertical trench super junction MOSFET device 200 with integrated snubber taken along line A-A of FIG. 1. The device 200 illustrates a p-doped pillar 206 and an n-doped pillar 208. Alternatively, inter-diffusion of dopants in the n-doped and p-doped columns in a super junction drain structure of a super-junction MOSFET can be reduced by creating an isolation structure 216 (i.e., a trench filled with isolation materials) between an n-doped pillar 208 and the p-doped pillar 206 in the device 200. In example implementations, the isolation structure 216 can have a vertical depth (e.g., in a y direction) comparable to a vertical thickness of a drain region (e.g., n-doped pillar 208) of the device 200. Further, the isolation structure 216 has a lateral width 218 (e.g., in an x-direction)) parallel to an upper surface of semiconductor substrate. In example implementations, the lateral width 218 of the isolation structure 216 in a top or upper vertical portion of the device 200 may be substantially larger than the width 218 of the isolation structure 216 in a lower vertical portion of the device 200.

The n-doped pillar 208 includes a gate structure 210 that may include a conductive material that is charged with the gate voltage to create an inversion layer or channel in a body region 240. A gate oxide 242 between the gate structure 210 and the body region 240 blocks current from flowing between the gate structure 210 and source 250 when a gate voltage signal is applied to the device 200. When an inversion layer or channel is formed in body region 240, current is able to flow from the drain (i.e., n-doped pillar 208) across the body region 240 to the source 250. The source 250 is electrically connected to a source plate 224 through a source contact 222.

The embodiment illustrated in FIG. 2 also shows a P-doped pillar contact 236. The P-doped pillar contact 236 protrudes (i.e., in the y direction) through the surface of the device 200 into the center of the P-doped pillar 206. The pillar contact 236 electrically connects the source plate 224 to the p-doped pillar 206. As illustrated, embodiments of the device 200 may have the source contacts 222 protrude deeper than the P-doped pillar contacts 236.

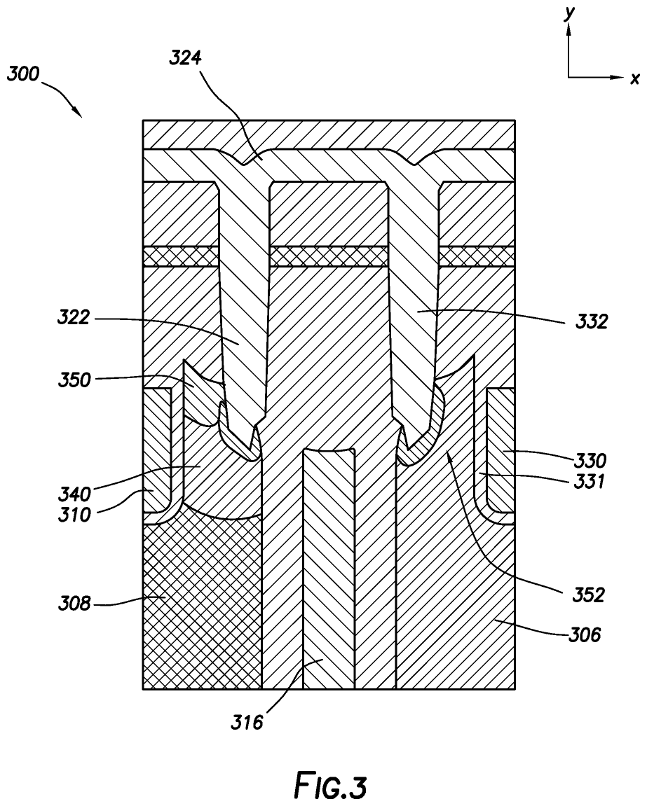

FIG. 3 is a cross-sectional side view of an embodiment of a vertical trench super-junction MOSFET device 300 with integrated snubber taken along line B-B of FIG. 1. As with the device 200 of FIG. 2, the device 300 in FIG. 3 illustrates a p-doped pillar 306 and an n-doped pillar 308. The pillars 306, 308 are separated by an isolation structure 316. The device 300 also has a similar gate structure 310 that forms a channel in body region 340 for current to pass from the drift region (i.e., n-doped pillar 308) to a source 350, a source contact 322, and a source plate 324. In the device 300 of FIG. 3, however, the p-doped pillar 306 includes a gate capacitive structure 330 and a P-doped pillar contact 332. Unlike the P-doped pillar contact 236 in FIG. 2, P-doped pillar contact 332 is located off from the center of P-doped pillar 306 in order to make room for the gate capacitive structure 330. The gate capacitive structure 330 is shaped and located similarly to the gate structure 310. That is, the gate capacitive structure 330 may include a conductive material surrounded by a gate oxide 331. Alternatively or additionally, the oxide 331 in the gate capacitive structure 330 may be of a different thickness than the gate oxide surrounding the gate structure 310 in order to provide a different specific capacitance value, a different breakdown voltage capability, or some other reason. The gate capacitive structure 330 does not create a channel region connecting drain and source since it is disposed in a P-doped pillar 306 and not an N-doped pillar 308. However, the gate capacitive structure 330 still capacitively couples to a surface doped region 352 in the P-doped pillar 306, similar to the way gate structure 310 capacitively couples to body region 340. In the cross-section depicted by FIG. 3, additional gate-source capacitance is added to the device, but little damping resistance is provided because P-doped pillar contact 332 provides a low resistance path between surface doped region 352 and source plate 324.

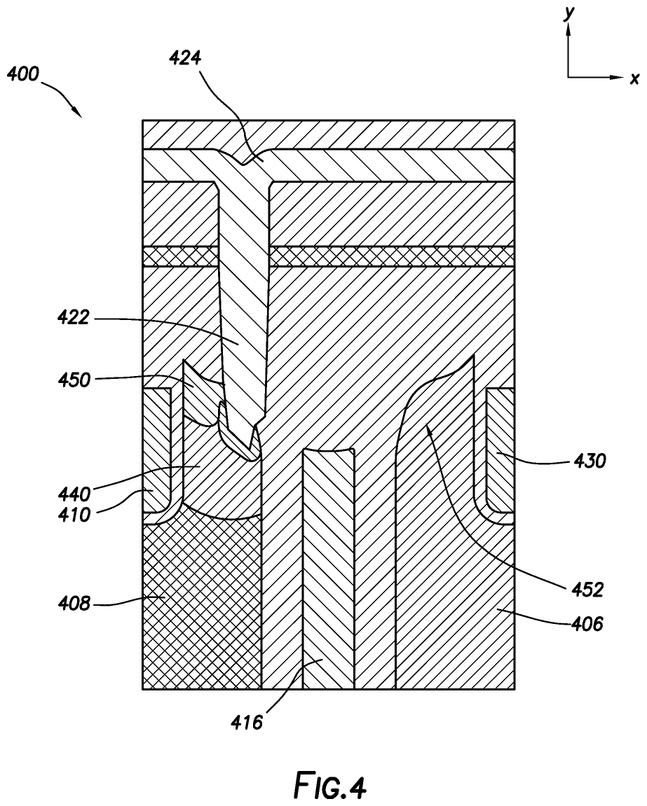

FIG. 4 is a cross-sectional side view of an embodiment of a vertical trench super junction MOSFET device 400 with integrated snubber taken along line C-C of FIG. 1. As with the devices 200, 300 of FIGS. 2 and 3, the device 400 in FIG. 4 illustrates a p-doped pillar 406 and an n-doped pillar 408. The pillars 406, 408 are separated by an isolation structure 416. The device 400 also has a similar gate structure 410 that forms a channel in a body region 440 for current to pass from the drain region to a source 450, a source contact 422, and a source plate 424. In the device 400 of FIG. 4, however, the p-doped pillar 406 includes a gate capacitive structure 430 without a P-doped pillar contact (e.g., 236, 332 described above). Surface doped region 452 does not have a conduction path to source unless device 400 is located along the same P-doped pillar as a device with a P-doped pillar contact, such as device 300. FIG. 1 illustrates this relationship with cutlines B-B and C-C lying along the same p-pillar. Because device 400 does not have a P-doped pillar contact, resistance is encountered as current flows from surface doped region 452 to the nearest P-doped pillar contact (i.e. device 300) along a distance 134 within a P-doped pillar (FIG. 1). Thus, three different devices are realized: a device with a P-doped pillar contact without a gate capacitive structure (FIG. 2), a device with both a P-doped pillar contact and a gate capacitive structure (FIG. 3), and a device without a P-doped pillar contact but with a gate capacitive structure (FIG. 4). Furthermore, all three of these devices can be realized in the same layout (FIG. 1). This feature enables the design of an integrated snubber circuit with a snubbing capacitance and resistance that can be readily adjusted to meet a particular application need.

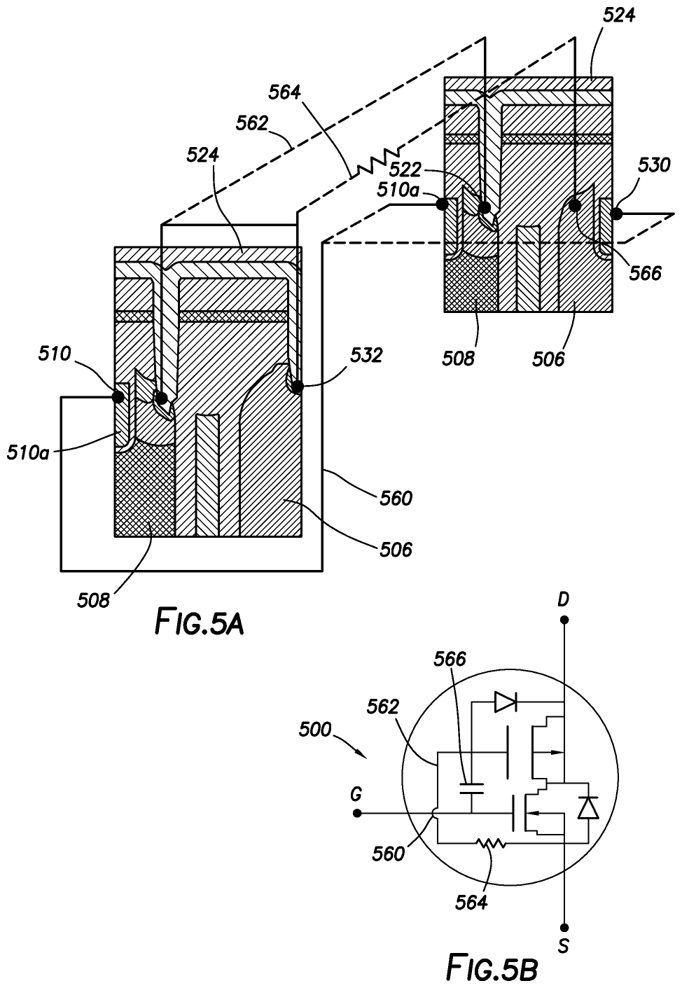

FIG. 5A is a schematic view of cross-sectional side views showing resistive and capacitive connections within a super-junction MOSFET device 500. The device 500 includes p-doped pillars 506 and n-doped pillars 508. In FIG. 5, the p-doped pillars 506 and the n-doped pillar 508 may be located along the same trench, or may be cross-sectional views of different trenches (e.g., trenches 102 from FIG. 1). The FIG. 5 illustrates connections that indicate an electrical or a capacitive connection between the end points of the connections. For example, a gate structure connection line 560 indicates an electrical connection between gate structure arms 510a and a gate capacitive structure 530 indicating that a gate structure 510 is electrically at a similar potential. The gate structure connection line 560 is also represented in FIG. 5B. The device 500 also illustrates a source connection line 562 in which source contacts 522, P-doped pillar contact 532, and a source plate 524 are all electrically connected at a similar potential. The device 500 also includes a resistive element 564 that is introduced to the source connection line 562 through the p-doped pillar 506. Likewise, a capacitive element 566 is introduced between the gate connection line 560 and the source connection line 562 across the oxide separating gate capacitive structure 530 from p-doped pillar 506.

As shown in FIG. 5B, the resistive element 564 and the capacitive element 566 provide an integrated snubber to the device 500. The resistive element 564 connects the capacitive element 566 to a source terminal S (e.g., source plate 524), which affects the gate signal that provides a voltage to enable a current conduction path between source and drain. That is, the elements 564, 566 slow down the gate signal in such a way that the gate signal does not bounce as much when it is turned on. This reduces the likelihood of problems within the device 500 that may be caused by high or low signals.

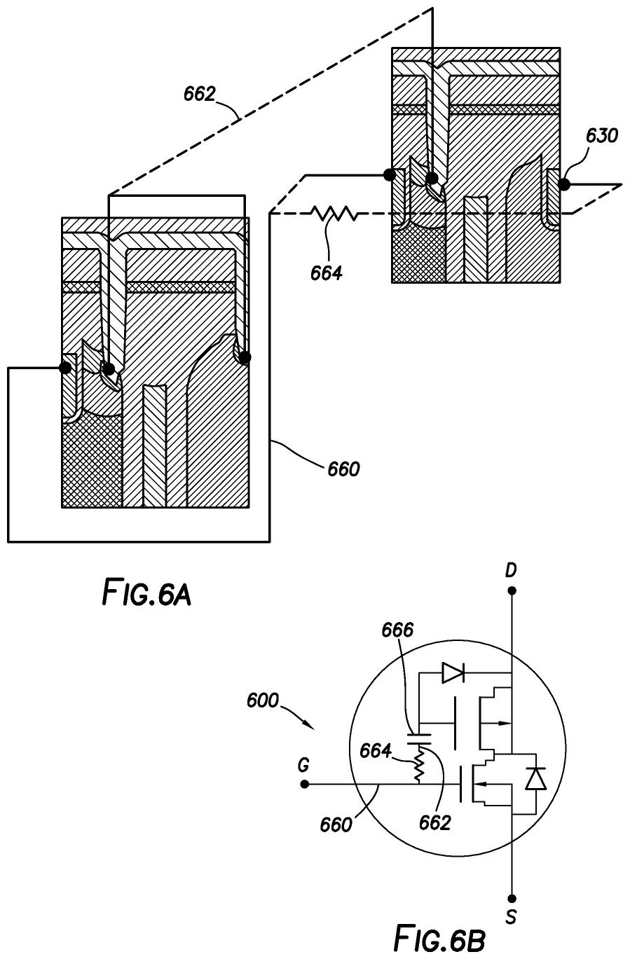

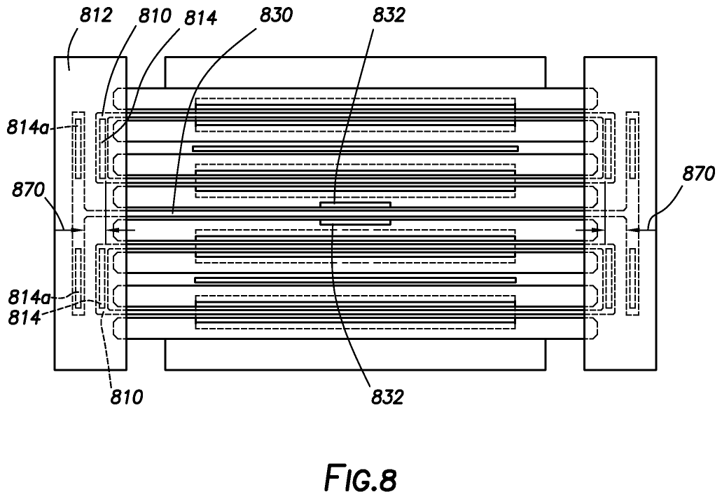

FIG. 6A illustrates that a device 600 also provides a circuit where the resistive element 664 connects the capacitive element 666 to a gate terminal G (e.g., common gate bus 112, gate contacts 114, gate structure 210, etc.). That is, in certain embodiments, the gate connection line 660 may include a resistive element 664. This resistive element 664 may be realized, for example, by separating a gate capacitive structure 830 from the gate structure 810 as shown in FIG. 8. Embodiments have been presented where the gate-source capacitive element 566 or 666 can be connected to either the source S or the gate G through an additional resistive element 564 or 664 respectively. In general, the two embodiments (source-side versus gate-side resistance), may have different electrical behaviors. In particular, the P-doped pillar 506 or 606 is capacitively coupled to the drain through the adjacent N-doped pillar 508 or 608 and the underlying substrate. This capacitive coupling adds a drain-source capacitive element which can feedback into the gate-source capacitance when there is source-side resistance or when the P-doped pillar is left floating without any P-doped pillar contact. By adjusting the amount of source-side versus gate-side resistance, the contribution of this drain-source capacitive feedback can be selected.

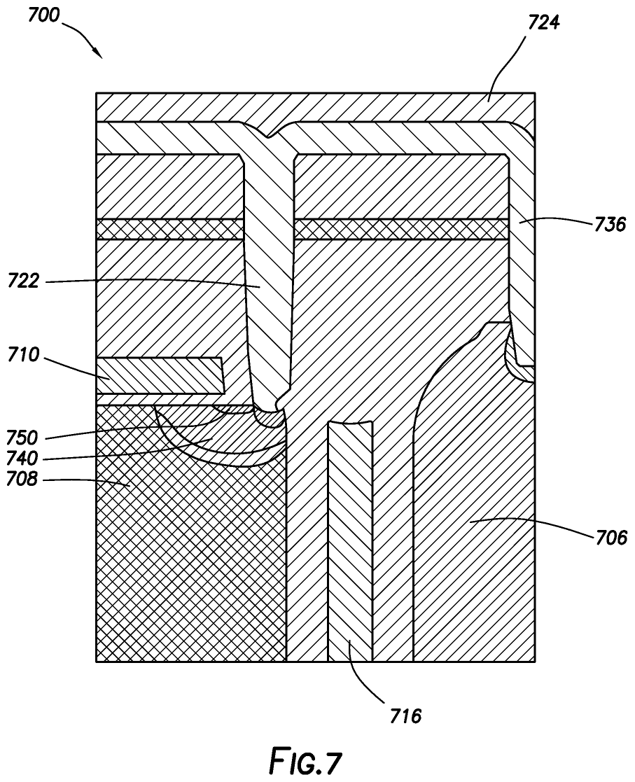

FIG. 7 is a cross-sectional side view of an embodiment of a planar trench super junction MOSFET device 700 with integrated snubber taken along line A-A of FIG. 1, as an alternative or additional embodiment to the device 200 in FIG. 2. As with the device 200 of FIG. 2, the device 700 in FIG. 7 illustrates a p-doped pillar 706 and an n-doped pillar 708. The pillars 706, 708 are separated by an isolation structure 716. The device 700 has a gate structure 710 that opens a channel in a body region 740 for a current to pass through to a source 750, a source contact 722, and a source plate 724. In the device 700 of FIG. 7, however, the signal passes through the channel at the top of 740 laterally (i.e., in the x direction) rather than vertically. The same gate capacitive structure, resistive structure, and source capacitive structure may be disposed in the planar embodiment of the device 700, or in other vertical or planar devices. For example, as illustrated in FIG. 7, the device 700 has a P-doped pillar contact 736 that functions in the same way that the P-doped pillar contact 236 of FIG. 2.

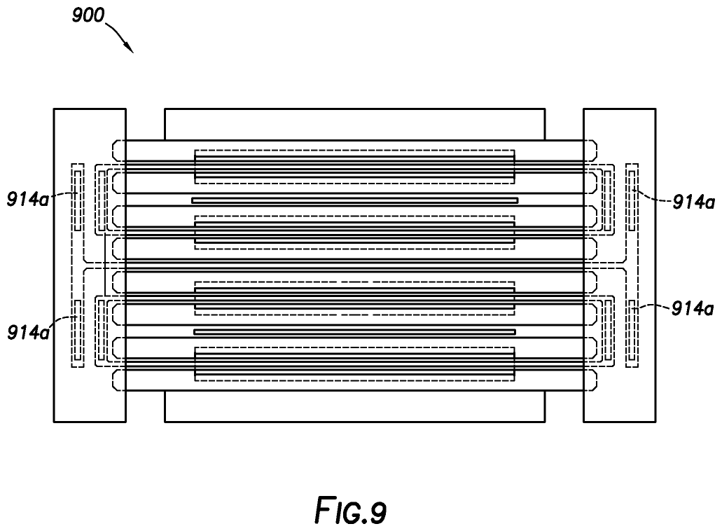

FIGS. 8 and 9 are plan view layouts of embodiments of super-junction MOSFET devices 800, 900 with an integrated snubber. The device 800 of FIG. 8 includes separation of gate structure 810 and gate capacitive structure 830. The separation is accomplished by providing the gate capacitive structure 830 with gate contacts 814a that provide the gate voltage specifically to the gate capacitive structure 830, whereas gate contacts 814 provide the gate voltage specifically to the gate structure 810. A common gate bus 812 provides the common gate voltage to each of the gate contacts 814, 814a, but the gate capacitive structure 830 has a different resistance value based on the extra length 870. The gate capacitive structure 830 may also be tuned to the circuit of the device 800 by adjusting other physical properties such as width, depth, or material composition. For example, a thinner gate capacitive structure 830 would increase the resistance to the gate voltage signal.

FIG. 8 also illustrates that P-doped pillar contacts 832 may be disposed on the device 800. In an additional or alternative embodiment, the device 900 of FIG. 9 illustrates that P-doped pillar contacts (e.g., P-doped pillar contacts 132, 832) are not required, and the resistance and capacitance properties may be adjusted using other components. Thus, bouncing of the gate voltage signal may be improved by tuning various properties of a device circuit by adjusting gate capacitive structures, resistive structures, source capacitive structures, or combinations thereof.

1. A semiconductor device, comprising:
an N-doped pillar comprising a gate structure configured to control a signal between a drain and a source in response to a gate voltage signal; and
a P-doped pillar comprising a capacitive structure, wherein the capacitive structure capacitively couples the P-doped pillar to the gate structure to reduce ringing in the gate voltage signal.

2. The device of claim 1, wherein the gate structure comprises a gate oxide surrounding a conductive material and the capacitive structure comprises an oxide surrounding a conductive material.

3. The device of claim 1, wherein the gate oxide and the oxide comprise different thicknesses.

4. The device of claim 1, comprising a pillar contact between the P-doped pillar and a source plate, and a source contact between the N-doped pillar and the source plate.

5. The device of claim 4, wherein the pillar contact comprises a length that is less than a length of the P-doped pillar.

6. The device of claim 4, comprising a second P-doped pillar comprising a pillar contact between the second P-doped pillar and the source plate, wherein the second P-doped pillar consists of doped layers of semiconductor material.

7. The device of claim 1, comprising an isolation structure, wherein the isolation structure separates the P-doped pillar from the N-doped pillar.

8. The device of claim 1, wherein the capacitive structure comprises a length that is the same as a length of the gate structure.

9. The device of claim 1, wherein the capacitive structure comprises a length that is different from a length of the gate structure.

10. The device of claim 1, wherein the gate structure comprises a vertical trench super-junction MOSFET.

11. The device of claim 1, wherein the gate structure comprises a planar super-junction MOSFET.

12. A method, comprising:
disposing an N-doped pillar and a P-doped pillar on a substrate, the N-doped pillar and the P-doped pillar being separated by an isolation structure;
disposing a source and a gate on the N-doped pillar; and
disposing a capacitive structure on the P-doped pillar, wherein the capacitive structure couples the P-doped pillar to the gate.

13. The method of claim 12, wherein disposing the capacitive structure comprises selecting a length for the capacitive structure that produces a chosen capacitance between the P-doped pillar and the gate.

14. The method of claim 12, wherein disposing the capacitive structure comprises selecting a length for a pillar contact that produces a chosen resistance in series with the chosen capacitance between the P-doped pillar and the gate.

15. The method of claim 12, comprising disposing a pillar contact between the P-doped pillar and a source plate.

16. A semiconductor device, comprising:
a substrate comprising N-doped pillars and P-doped pillars, wherein in at least one of the N-doped pillars comprises a gate structure;
a common gate bus electrically coupled to the gate structure; and
a gate capacitive structure electrically coupled to the common gate bus, wherein the capacitive structure is disposed within a capacitive P-doped pillar selected from the P-doped pillars.

17. The device of claim 16, comprising a P-doped pillar contact between the capacitive P-doped pillar and a source contact.

18. The device of claim 17, wherein the P-doped pillar contact comprises a length that is less than a length of the capacitive P-doped pillar.

19. The device of claim 16, wherein the N-doped pillars comprise a vertical trench MOSFET, a planar gate MOSFET, or combination thereof.

20. The device of claim 16 comprising isolation structures between the N-doped pillars and the P-doped pillars.
